(19) United States
(12) Patent Application Publication
(10) Pub. No.: US 2024/0347423 A1
(43) Pub. Date: Oct. 17, 2024

(54) METAL CONTACT CONNECTION THROUGH DIFFUSION BREAK AREA

(71) Applicant: INTERNATIONAL BUSINESS MACHINES CORPORATION, ARMONK, NY (US)

(72) Inventors: Sagarika Mukesh, ALBANY, NY (US); Shravana Kumar Katakam, Lehi, UT (US); Tao Li, Slingerlands, NY (US); Ruilong Xie, Niskayuna, NY (US); Nicholas Anthony Lanzillo, Wynantskill, NY (US); Julien Frougier, Albany, NY (US)

(21) Appl. No.: 18/298,402

(22) Filed: Apr. 11, 2023

(51) Int. Cl. H01L 23/48; H01L 21/8234; H01L 27/088; H01L 29/06; H01L 29/423; H01L 29/66; H01L 29/775; H01L 29/786

(52) U.S. Cl. CPC H01L 23/481; H01L 21/823412; H01L 21/823475; H01L 27/088; H01L 29/0673; H01L 29/42392; H01L 29/66439; H01L 29/66545; H01L 29/775; H01L 29/78696

(57) ABSTRACT

Embodiments of present invention provide a semiconductor structure. The structure includes an array of transistors on a semiconductor substrate, the array of transistors including a first transistor and a second transistor, the second transistor being next to the first transistor; and a metal connection between the first transistor and the second transistor, wherein the metal connection connects a first metal contact at a frontside of the array of transistors to a second metal contact at a backside of the array of transistors. A method of forming the same is also provided.

### BACKGROUND

The present application relates to manufacturing of semiconductor integrated circuits. More particularly, it relates to a metal connection made through a diffusion break area and method of manufacturing the same.

With the introduction of backside power distribution network (BSPDN), power connection between a frontside and a backside of a semiconductor chip or substrate has been actively studied, investigated and various structures have been proposed. For example, one existing approach is to connect frontside active devices to BSPDN through buried power rail (FSBPR) at the frontside and through-silicon-via (TSV) such as nano TSV (nTSV) at the backside. However, this approach only applies to situations where all power lines come from the BSPDN at the backside and no power line exists, at the frontside, at the back-end-of-line (BEOL) level. Moreover, this approach may introduce limitation on the routing capability of the chip, especially for stacked transistors.

### SUMMARY

Embodiments of present invention provide a semiconductor structure. The semiconductor structure includes an array of transistors on a semiconductor substrate, the array of transistors including a first transistor and a second transistor, the second transistor being next to the first transistor; and a metal connection between the first transistor and the second transistor, wherein the metal connection connects a first metal contact at a frontside of the array of transistors to a second metal contact at a backside of the array of transistors.

In one embodiment, a source/drain region of the first transistor and a source/drain region of the second transistor are replaced by the metal connection, rendering the first transistor being a first dummy transistor and the second transistor being a second dummy transistor.

In another embodiment, the first dummy transistor includes a first dummy gate that surrounds a first set of nanosheets, the first set of nanosheets has a first section adjacent to the metal connection and a second section adjacent to a source/drain region of an active transistor, wherein the first section and the second section of the first set of nanosheets comprise different material.

In yet another embodiment, the first section of the first set of nanosheets includes a dielectric material and the second section of the first set of nanosheets includes a silicon material, and the first section of the first set of nanosheets electrically isolates the metal connection from the second section of the first set of nanosheets.

In one embodiment, the metal connection is further electrically isolated from the first dummy gate by a plurality of inner spacers between the first set of nanosheets and by a sidewall spacer above the first set of nanosheets.

In another embodiment, the metal connection includes a first portion between the first and the second dummy gate and the first and the second set of nanosheets, and a second section that is surrounded by a backside interlevel dielectric layer underneath the first and the second dummy transistor.

According to one embodiment, the first dummy transistor includes a first dummy gate that surrounds an end of a first set of nanosheets, and the metal connection is separated from the end of the first set of nanosheets at least by the first dummy gate.

In one embodiment, the metal connection includes a first portion between the first and the second dummy transistor, and a second portion that is surrounded by a dummy diffusion break, and the dummy diffusion break is further surrounded by a backside interlevel dielectric layer underneath the first and the second dummy transistor.

Embodiments of present invention provide a method of forming a semiconductor structure. The method includes forming an array of transistors on a substrate, the array of transistors including a first transistor and a second transistor, the second transistor being next to the first transistor; forming a sacrificial placeholder in the substrate between the first and the second transistor; forming a first portion of a metal connection above the sacrificial placeholder between the first and the second transistor; and forming a second portion of the metal connection in a backside interlevel dielectric layer directly underneath the first portion of the metal connection.

In one embodiment, forming the array of transistors includes forming a raw stack of nanosheets on top of the substrate; and recessing the raw stack of nanosheets to create a first set of nanosheets and a second set of nanosheets, the first transistor includes the first set of nanosheets, and the second transistor includes the second set of nanosheets.

In another embodiment, forming the array of transistors further includes performing a selective etching process of the first and the second set of nanosheets via an opening between the first and the second transistor to create a first set of indentations at the first set of nanosheets and a second set of indentations at the second set of nanosheets.

In one embodiment, the method further includes depositing a dielectric layer into the first and the second set of indentations at the first and the second set of nanosheets and on top of the sacrificial placeholder, wherein forming the first portion of the metal connection comprises forming the first portion of the metal connection in the dielectric layer.

In another embodiment, forming the second portion of the metal connection includes replacing the sacrificial placeholder with the second portion of the metal connection through a deposition process from a backside of the array of transistors.

According to one embodiment, the method further includes forming a dummy diffusion break in the substrate between the first and the second transistor; and forming the sacrificial placeholder in the dummy diffusion break to be surrounded by the dummy diffusion break.

In one embodiment, forming the second portion of the metal connection includes selectively removing the sacrificial placeholder from the dummy diffusion break, and filling an opening created by the removal of the sacrificial placeholder with the second portion of the metal connection.

### BRIEF DESCRIPTION OF THE DRAWINGS

The present invention will be understood and appreciated more fully from the following detailed description of embodiments of present invention, taken in conjunction with accompanying drawings of which:

FIGS. 1-9 are demonstrative illustrations of cross-sectional views of a semiconductor structure at various steps of manufacturing thereof according to one embodiment of present invention;

FIGS. 10-17 are demonstrative illustrations of cross-sectional views of a semiconductor structure at various steps of manufacturing thereof according to another embodiment of present invention; and

FIG. 18 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

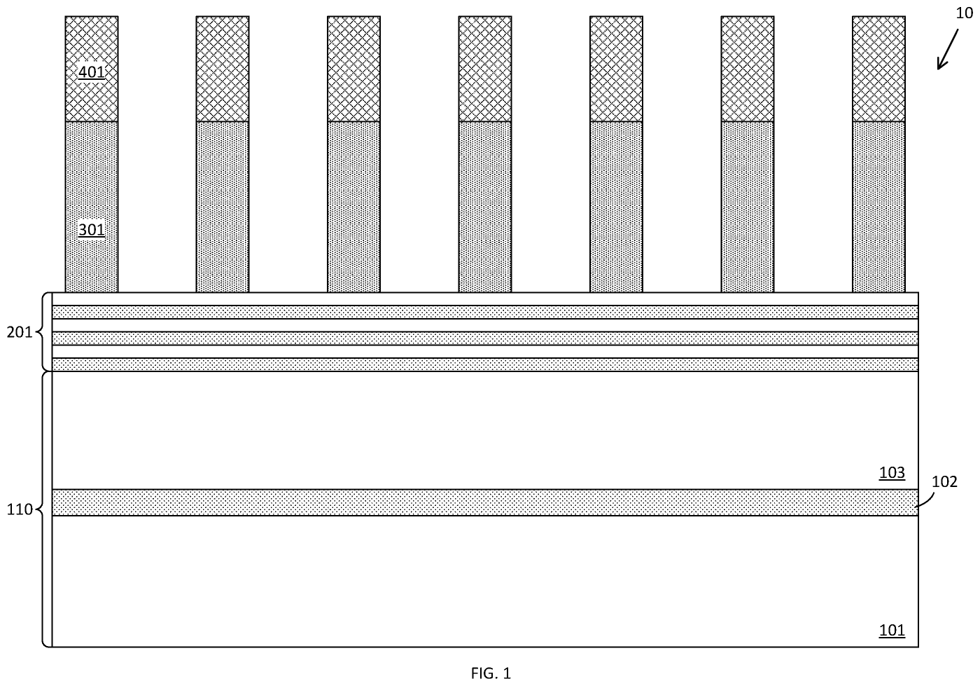

FIGS. 1-9 are demonstrative illustrations of cross-sectional views of a semiconductor structure at various steps of manufacturing thereof according to one embodiment of present invention. For example, FIG. 1 is a demonstrative illustration of a cross-sectional view of a semiconductor structure in a step of manufacturing thereof according to one embodiment of present invention. More particularly, embodiments of present invention provide forming a semiconductor structure 10 by providing or forming a semiconductor substrate 110. The semiconductor substrate 110 may include a bulk silicon substrate 101, an etch-stop layer 102 on top of the bulk silicon substrate 101, and a silicon layer 103 on top of the etch-stop layer 102. The etch-stop layer 102 may be a dielectric layer. Alternatively, semiconductor substrate 110 may be a silicon-on-insulator (SOI) substrate.

Embodiments of present invention further provide forming or patterning a raw stack of nanosheets 201 on top of the substrate 110. Subsequently, a set of sacrificial gates 301 may be formed on top of the raw stack of nanosheets 201. The set of sacrificial gates 301 may be formed through a lithographic patterning and etching process such as, for example, by patterning or forming a set of hard masks 401 on top of a layer of dummy gate material and etch the layer of dummy gate material, using the hard masks 401 in a selective etching process, to form the set of sacrificial gates 301. In one embodiment, the set of sacrificial gates 301 may be polysilicon in material. The hard masks 401 may be, for example, silicon-nitride (SiN).

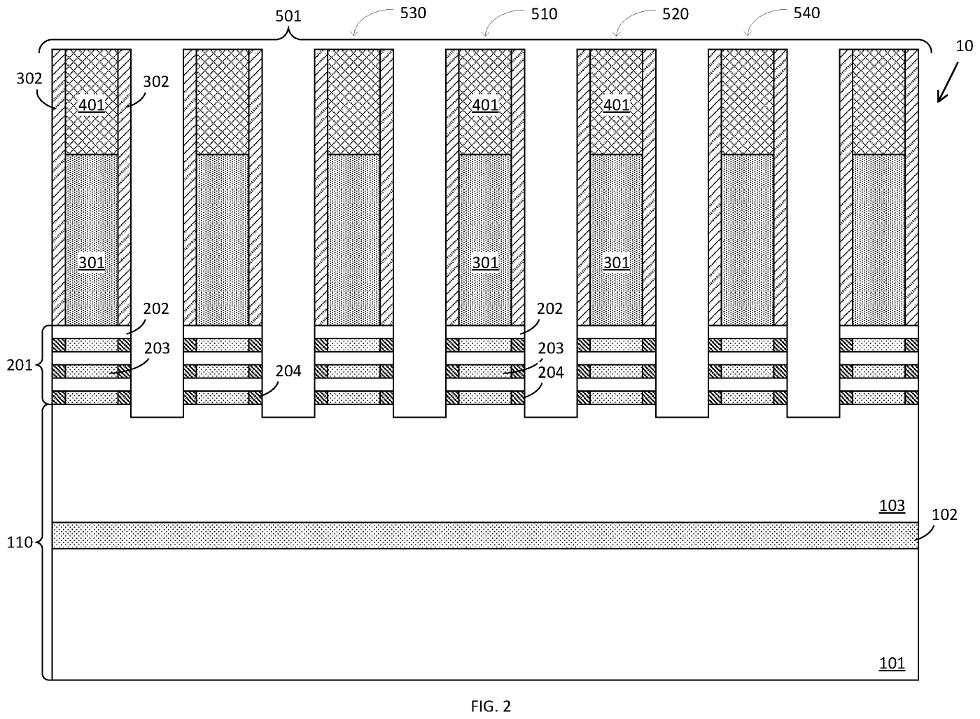

FIG. 2 is a demonstrative illustration of a cross-sectional view of a semiconductor structure in a step of manufacturing thereof according to one embodiment of present invention. More particularly, following the step illustrated in FIG. 1, embodiments of present invention provide forming sidewall spacers 302 at sidewalls of the set of sacrificial gates 301, and recessing or etching the raw stack of nanosheets 201 to create a plurality of stacks of nanosheets, which subsequently forms an array of transistors 501. For example, the array of transistors 501 may include a first set of transistors and a second set of transistors. As will be described below in more details, the first set of transistors may include a first dummy transistor 510 and a second dummy transistor 520, and the second set of transistors may include a first active transistor 530 and a second active transistor 540. As is illustrated in FIG. 2, the second dummy transistor 520 may be next to the first dummy transistor 510. The first active transistor 530 may be next to the first dummy transistor 510 and opposite the second dummy transistor 520. The second active transistor 540 may be next to the second dummy transistor 520 and opposite to the first dummy transistor 510.

On the other hand, in forming the array of transistors 501, the plurality of stacks of nanosheets may each include a set of nanosheets 202 and a set of sacrificial sheets 203 that is vertically between the set of nanosheets 202. For example, the first dummy transistor 510 may include a first set of nanosheets 202 and the second dummy transistor 520 may include a second set of nanosheets 202. Embodiments of present invention may further provide forming inner spacers 204 at the two ends of the set of sacrificial sheets 203. The inner spacers 204 may be created by first recessing the sacrificial sheets 203 at the two ends thereof, and then depositing a layer of dielectric material in the recessed areas.

In one embodiment, the sidewall spacers 302 and the inner spacers 204 may be nitride such as silicon-nitride (SiN); the set of nanosheets 202 may be silicon (Si) or silicon-germanium (SiGe) with a first germanium (Ge) concentration level; and the set of sacrificial sheets 203 may be SiGe with a second Ge concentration level. The Ge concentration level of the set of nanosheets 202 may range, for example, from 25% to 35% and may be different from the Ge concentration level of the set of sacrificial sheets 203, which may range, for example, from 45% to 55%, such that the set of sacrificial sheets 203 may be selectively removed or etched away in the presence of set of nanosheets 202, as being described below in more details.

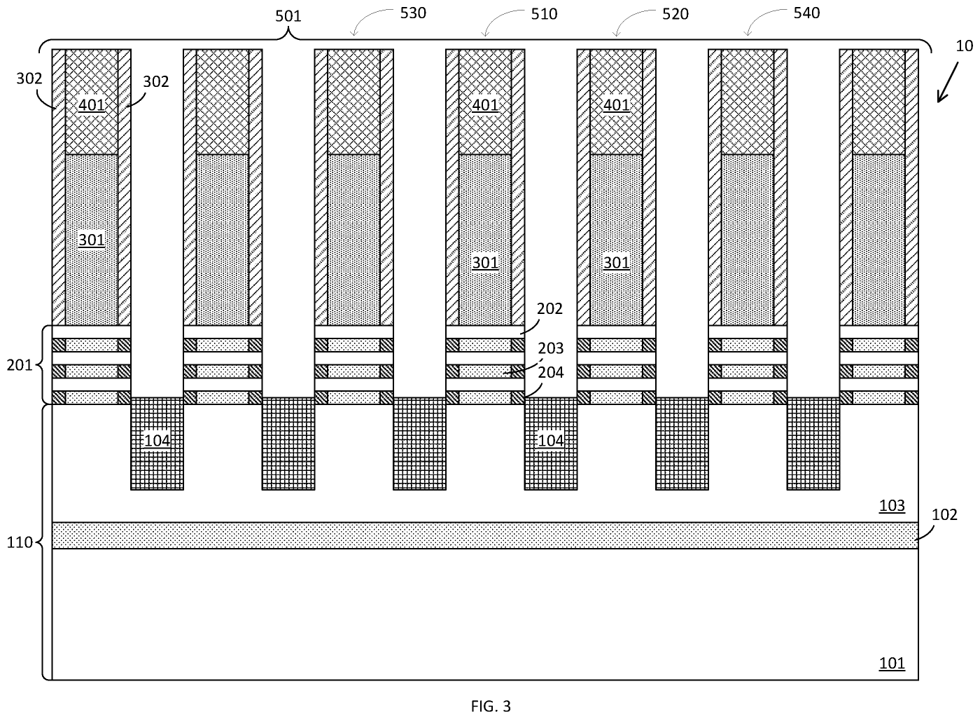

FIG. 3 is a demonstrative illustration of a cross-sectional view of a semiconductor structure in a step of manufacturing thereof according to one embodiment of present invention. More particularly, following the step illustrated in FIG. 2, embodiments of present invention provide forming a set of sacrificial placeholders 104 in the silicon layer 103 and in areas between the array of transistors 501 or more particularly between the set of sacrificial gates 301. The set of sacrificial placeholders 104 may be made by first recessing, through a selective etching process, the silicon layer 103 to create recesses and subsequently depositing a material suitable for the sacrificial placeholders 104 such as, for example polysilicon, silicon-oxide (SiO₂), or silicon-nitride (SiN), in the created recesses in the silicon layer 103. In one embodiment, at least one of the sets of sacrificial placeholders 104 is formed between the first dummy transistor 510 and the second dummy transistor 520 in the silicon layer 103 in an area where a double diffusion break is usually formed.

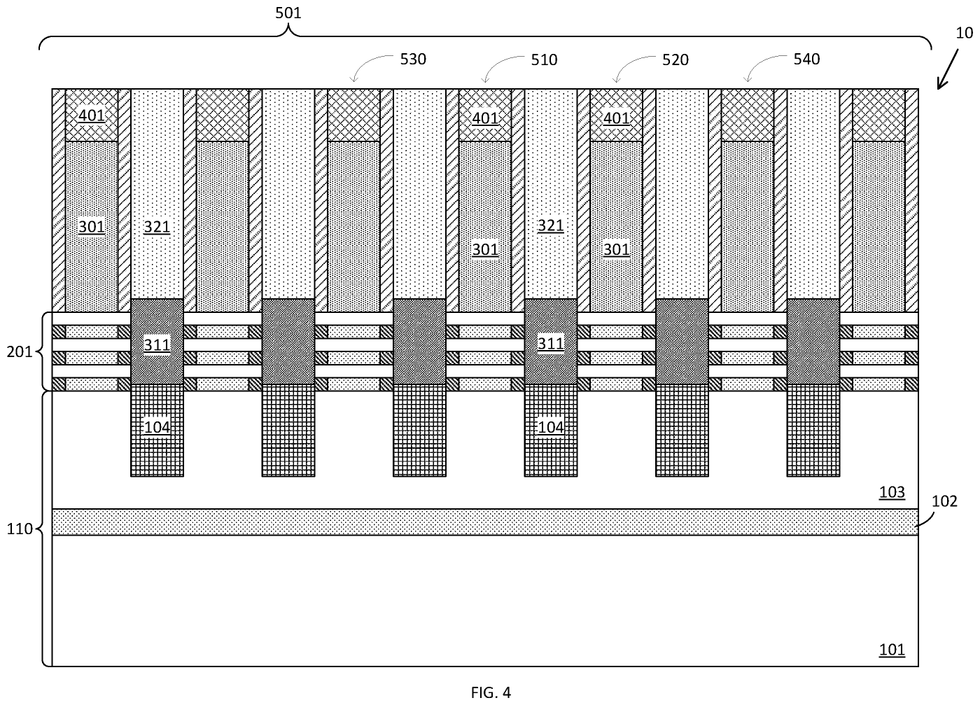

FIG. 4 is a demonstrative illustration of a cross-sectional view of a semiconductor structure in a step of manufacturing thereof according to one embodiment of present invention. More particularly, following the step illustrated in FIG. 3, embodiments of present invention provide forming source/drain regions 311 of the array of transistors 501 through an epitaxial growth process. The source/drain regions 311 may be formed between the ends of any two neighboring stacks of nanosheets, such as between the nanosheets 202 and between the inner spacers 204. The source/drain regions 311 may be formed directly above the sacrificial placeholders 104 and may include Si or SiGe in material. Following the formation of the source/drain regions 311, embodiments of present invention provide filling the space or opening above the source/drain regions 311 that is between the sacrificial gates 301 with a dielectric layer 321. In one embodiment, the dielectric layer 321 may be an interlevel dielectric layer made of a material, such as SiO₂, that provide etch selectivity with the sidewall spacers 302 and the underneath sacrificial placeholders 104. A chemical-mechanic-polishing (CMP) process may subsequently be applied to planarize a top surface of the semiconductor structure 10, resulting in some portion of the hard masks 401 and sidewall spacers 302 being removed.

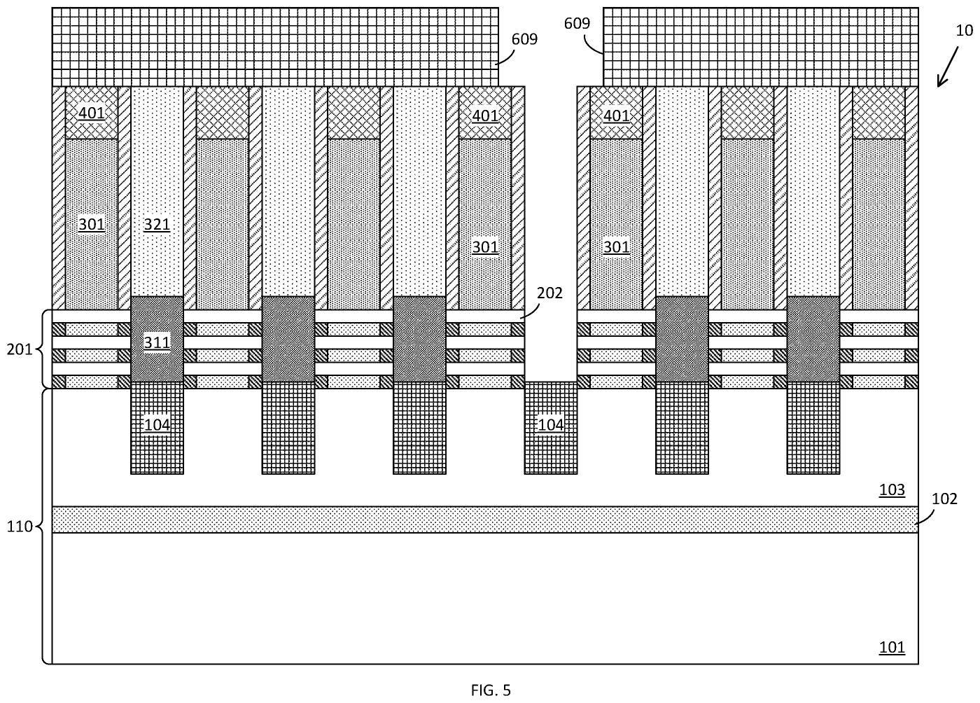

FIG. 5 is a demonstrative illustration of a cross-sectional view of a semiconductor structure in a step of manufacturing thereof according to one embodiment of present invention. More particularly, following the step illustrated in FIG. 4, embodiments of present invention provide forming an organic planarization layer (OPL) at the planarized top surface of the semiconductor structure 10 above the hard mask 401 and the dielectric layer 321, and patterning the OPL layer to form a hard mask 609. Because embodiments of present invention provide creating a metal contact connection in an area that is normally used for making a double diffusion break, a hard mask used in patterning the double diffusion break may be used or re-used here as the hard mask 609, thereby potentially reducing the cost of needing to create another new hard mask for the purpose of using as the hard mask 609. The hard mask 609 exposes the dielectric layer 321 between the first dummy transistor 510 and the second dummy transistor 520.

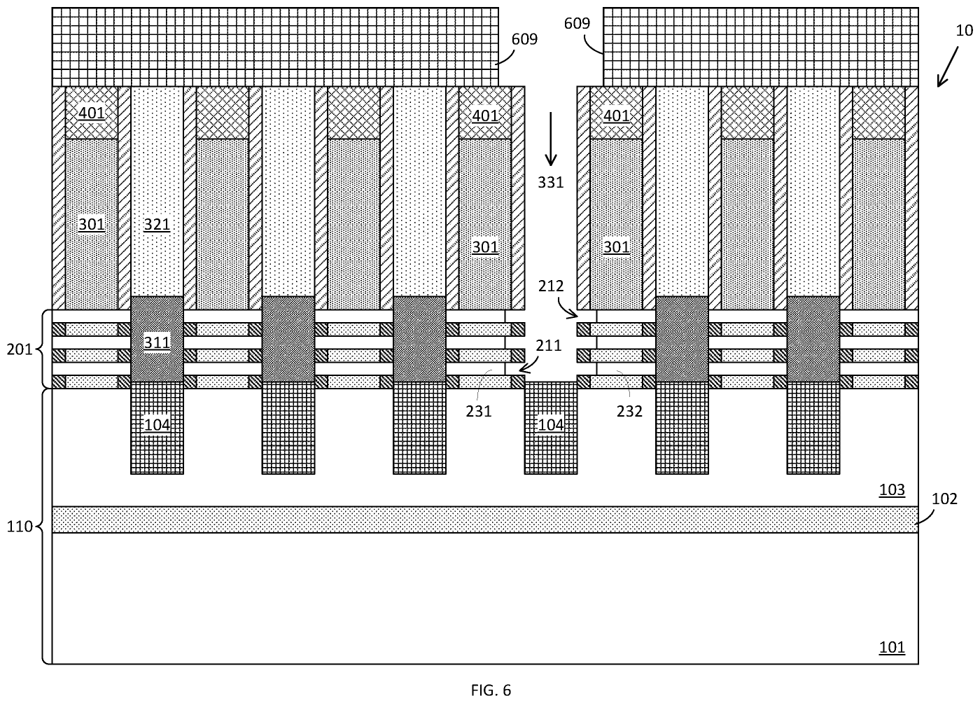

FIG. 6 is a demonstrative illustration of a cross-sectional view of a semiconductor structure in a step of manufacturing thereof according to one embodiment of present invention. More particularly, following the step illustrated in FIG. 5, embodiments of present invention provide selectively removing the dielectric layer 321, between the first and the second dummy transistor 510 and 520, and the underneath source/drain region 311 to expose the sacrificial placeholder 104 in the silicon layer 103 of the substrate 110. After removing the source/drain region 311, the first and the second set of nanosheets 202 of the first and the second dummy transistor 510 and 520 may also be exposed.

Embodiments of present invention further provide recessing an end portion of the exposed first set of nanosheets 202 of the first dummy transistor 510 to create indentations 211 and recessing an end portion of the exposed second set of nanosheets 202 of the second dummy transistor 520 to create indentations 212. In the meantime, the recessing creates a second portion 231 of the first set of nanosheets 202 of the first dummy transistor 510 next to a source/drain region 311 of the first active transistor 530 and creates a second portion 232 of the second set of nanosheets 202 of the second dummy transistor 520 next to a source/drain region 311 of the second active transistor 540. The recessing may be made through an opening 331, between the sacrificial gates 301 of the first and the second dummy transistor 510 and 520, in a selective etching process.

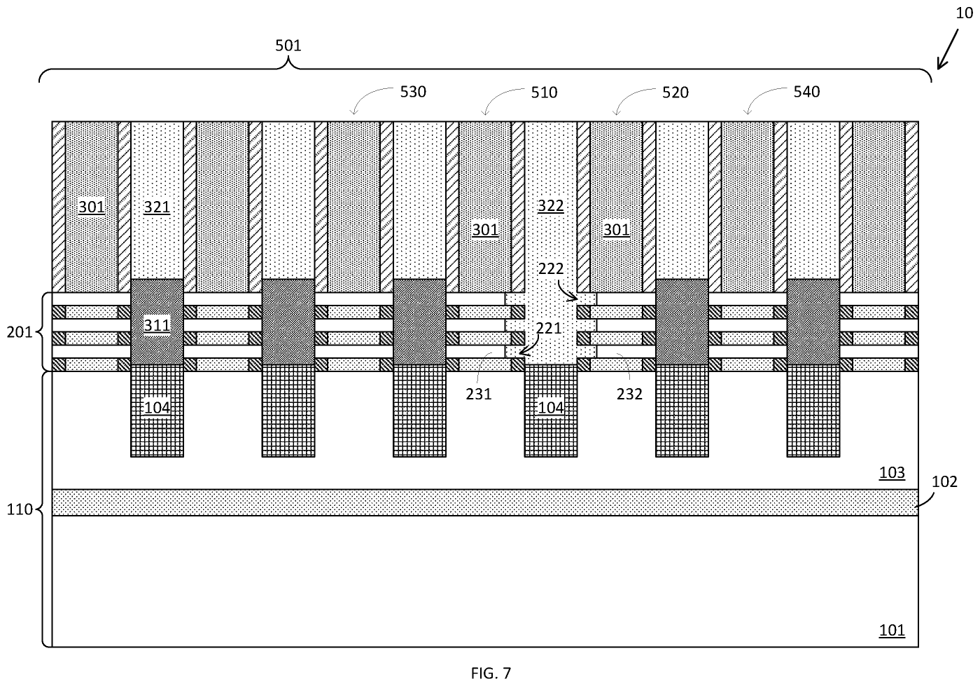

FIG. 7 is a demonstrative illustration of a cross-sectional view of a semiconductor structure in a step of manufacturing thereof according to one embodiment of present invention. More particularly, following the step illustrated in FIG. 6, embodiments of present invention provide filling the indentations 211 of the first dummy transistor 510 with a layer of dielectric material to create or form a first portion 221 of the first set of nanosheets 202 of the first dummy transistor 510 and to create or form a first portion 222 of the second set of nanosheets 202 of the second dummy transistor 520. Embodiments of present invention further provide forming a dielectric layer 322 above the sacrificial placeholder 104 and between the first and the second sacrificial gates 301. After forming the dielectric layer 322, a CMP process may be applied to polish and subsequently remove the hard masks 401 and create a planarized surface that exposes the sacrificial gates 301.

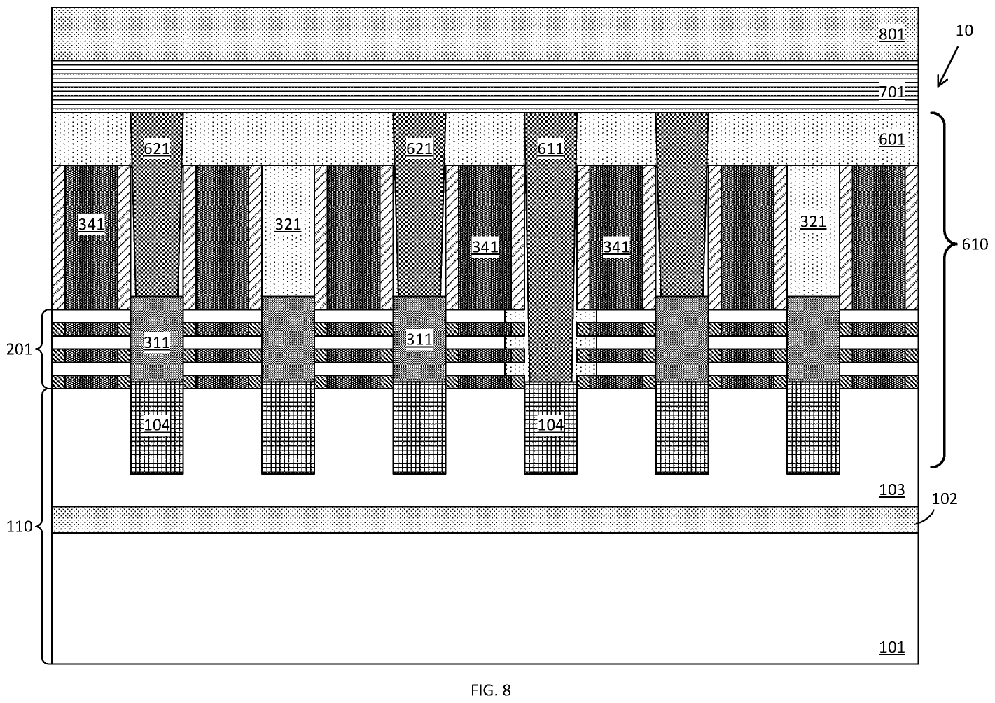

FIG. 8 is a demonstrative illustration of a cross-sectional view of a semiconductor structure in a step of manufacturing thereof according to one embodiment of present invention. More particularly, following the step illustrated in FIG. 7, embodiments of present invention provide selectively removing the sacrificial gates 301 and the set of sacrificial sheets 203 vertically between the set of nanosheets 202, and forming replacement metal gates 341 that surround or wrap around the set of nanosheets 202 as well as above the set of nanosheets 202. In one embodiment, the replacement metal gates 341 of the first and the second dummy transistor 510 and 520 may be dummy gates. Next, embodiments of present invention provide forming, such as through deposition, a dielectric layer 601 above the semiconductor structure 10, covering the replacement metal gates 341, the dielectric layer 321, and the dielectric layer 322 (see FIG. 7) between the first and the second dummy transistor 510 and 520.

Following the formation of the dielectric layer 601, one or more openings may be created, via a lithographic patterning and etching process, through the dielectric layer 601 and through the dielectric layer 322 to expose the underneath sacrificial placeholder 104, and through the dielectric layer 321 to expose one or more of the source/drain regions 311 of other active transistors such as the first active transistor 530 and/or the second active transistor 540. Next, a conductive material such as, for example, metal may be used to fill the opening or openings to form a first portion 611 of a metal connection 610 between the first and the second dummy transistor 510 and 520 and, for example, a source/drain contact 621 above one of the source/drain regions 311 of an active transistor such as the first active transistor 530.

Embodiments of present invention further provide forming other middle-of-line (MOL) structures and a back-end-of-line (BEOL) 701 on top of the dielectric layer 601 in contact with one or more of the source/drain contacts 621 and in contact with the first portion 611 of the metal connection 610 from the frontside of the semiconductor structure 10. For example, the BEOL 701 may include a metal contact that is in contact with the metal connection 610. A carrier wafer 801 is then bonded onto the semiconductor structure 10 for the purpose of further processing the semiconductor structure 10 from a backside thereof.

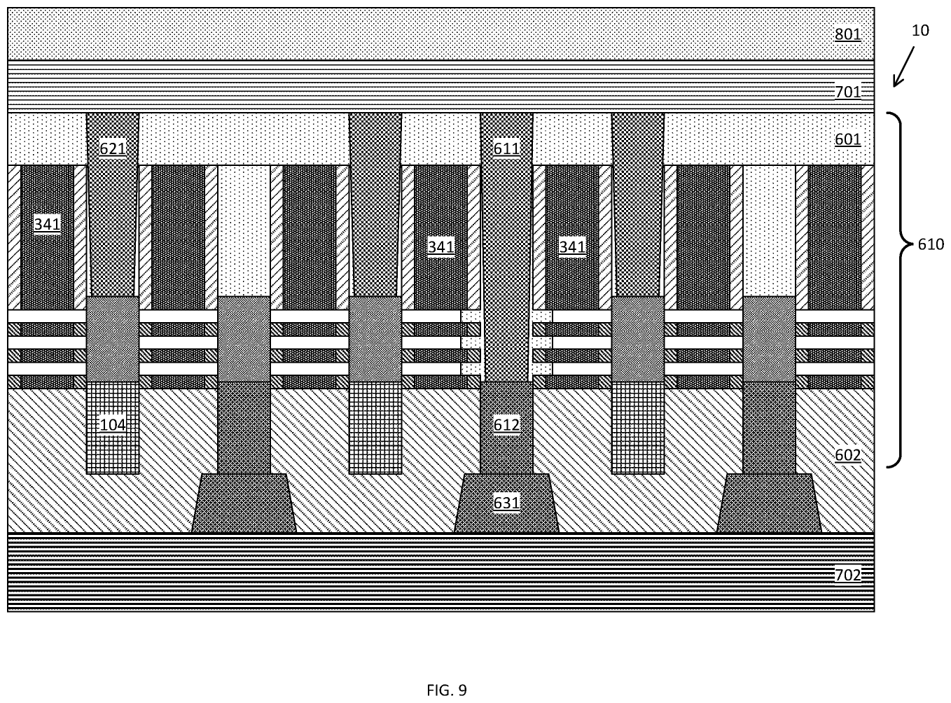

FIG. 9 is a demonstrative illustration of a cross-sectional view of a semiconductor structure in a step of manufacturing thereof according to one embodiment of present invention. More particularly, following the step illustrated in FIG. 8, embodiments of present invention provide removing the bulk silicon substrate 101 through a CMP process or a selective etching process to stop at the etch-stop layer 102, removing the etch-stop layer 102, and selectively removing the silicon layer 103 relative to the sacrificial placeholders 104. A backside interlevel dielectric layer 602 may then be formed to cover the backside of the plurality of stacks of nanosheets and the sacrificial placeholders 104. After forming the backside interlevel dielectric layer 602, one or more openings may subsequently be created in the backside interlevel dielectric layer 602, with one or more of the sacrificial placeholders 104, including at least the sacrificial placeholder 104 between the first and the second dummy transistors 510 and 520 being exposed. The exposed sacrificial placeholders 104 may be removed in a selective etching process. For example, a bottom surface of the first portion 611 of the metal connection 610 may be exposed by the removal of the sacrificial placeholder 104 underneath thereof. A conductive material such as metal, and in one embodiment a same metal as that used in forming the first portion 611 of the metal connection 610, may be used to form a second portion 612 of the metal connection 610. In other words, the metal connection 610 may include the first portion 611 and the second portion 612 with the first portion 611 and the second portion 612 being made of, in one embodiment, a same material such as metal.

Embodiments of present invention may further provide forming one or more backside contacts such as metal contacts in the backside interlevel dielectric layer 602 and at least one of the backside contacts, such as a backside contact 631, known as a backside contact via or metal contact, is in contact with the second portion 612 of the metal connection 610. A backside interconnect structure 702 may subsequently be formed above the one or more backside contacts and above the backside interlevel dielectric layer 602.

As is illustrated in FIG. 9, a source/drain region of the first transistor 510 is replaced by the metal connection 610, or more particularly by the first portion 611 of the metal connection 610, and therefore missing from the first transistor 510, rendering the first transistor 510 to become the first dummy transistor 510. Similarly, a source/drain region of the second transistor 520 is replaced by the metal connection 610, or more particularly by the first portion 611 of the metal connection 610, and therefore missing from the second transistor 520, rendering the second transistor 520 to become the second dummy transistor 520.

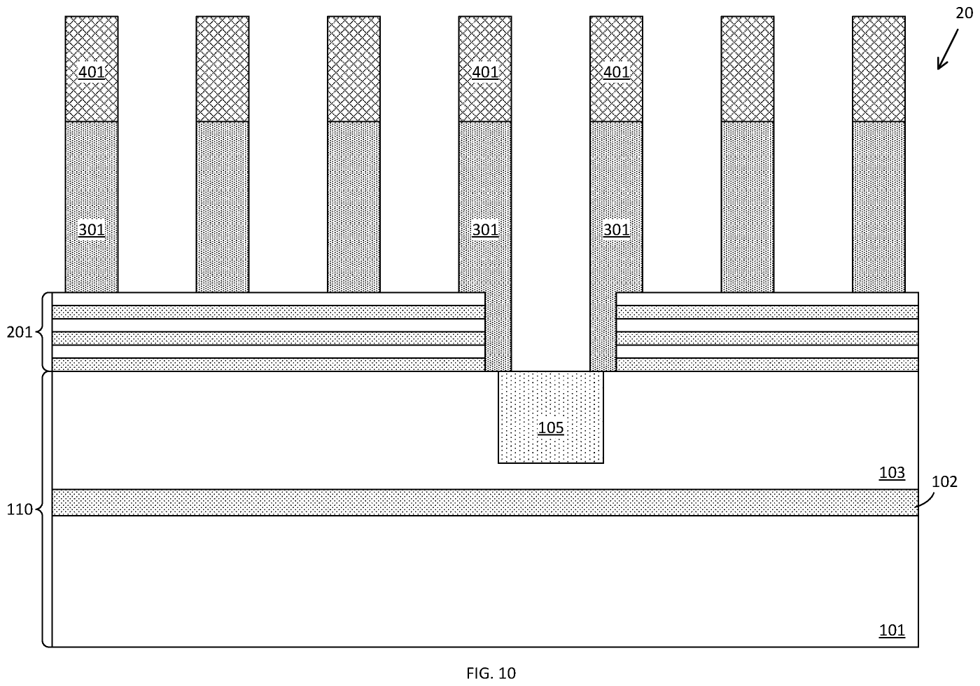

FIGS. 10-17 are demonstrative illustrations of cross-sectional views of a semiconductor structure at various steps of manufacturing thereof according to another embodiment of present invention. For example, FIG. 10 is a demonstrative illustration of a cross-sectional view of a semiconductor structure in a step of manufacturing thereof according to one embodiment of present invention. More particularly, embodiments of present invention provide forming a semiconductor structure 20 by providing or forming a semiconductor substrate 110 and patterning or forming a raw stack of nanosheets 201 on top of the substrate 110. The semiconductor substrate 110 may include a bulk silicon substrate 101, an etch-stop layer 102 which may be a dielectric layer on top of the bulk silicon substrate 101, and a silicon layer 103 on top of the etch-stop layer 102. In one embodiment, the semiconductor substrate 110 may be a SOI substrate.

Embodiments of present invention further provide forming a dummy diffusion break 105 in the silicon layer 103. The dummy diffusion break 105 may be formed after forming the raw stack of nanosheets 201 by breaking the raw stack of nanosheets 201 into two raw stacks of nanosheets, thereby creating an opening between the two raw stacks of nanosheets to expose the underneath silicon layer 103. The dummy diffusion break 105 may then be formed in the exposed portion of the silicon layer 103 through a patterning, etching, and deposition process. However, embodiments of present invention are not limited in this aspect and the dummy diffusion break 105 may be created or formed in the silicon layer 103 before forming the raw stack of nanosheets 201.

Subsequently, a set of sacrificial gates 301 may be formed on top of the raw stack of nanosheets 201. The set of sacrificial gates 301 may be formed through a lithographic patterning and etching process such as, for example, by patterning or forming a set of hard masks 401 on top of a layer of dummy gate material and then selectively etching the layer of dummy gate material to form the set of sacrificial gates 301. One of the sacrificial gates 301 may cover an end of one of the two raw stacks of nanosheets, and another one of the sacrificial gates 301 may cover an end of the other one of the two raw stacks of nanosheets.

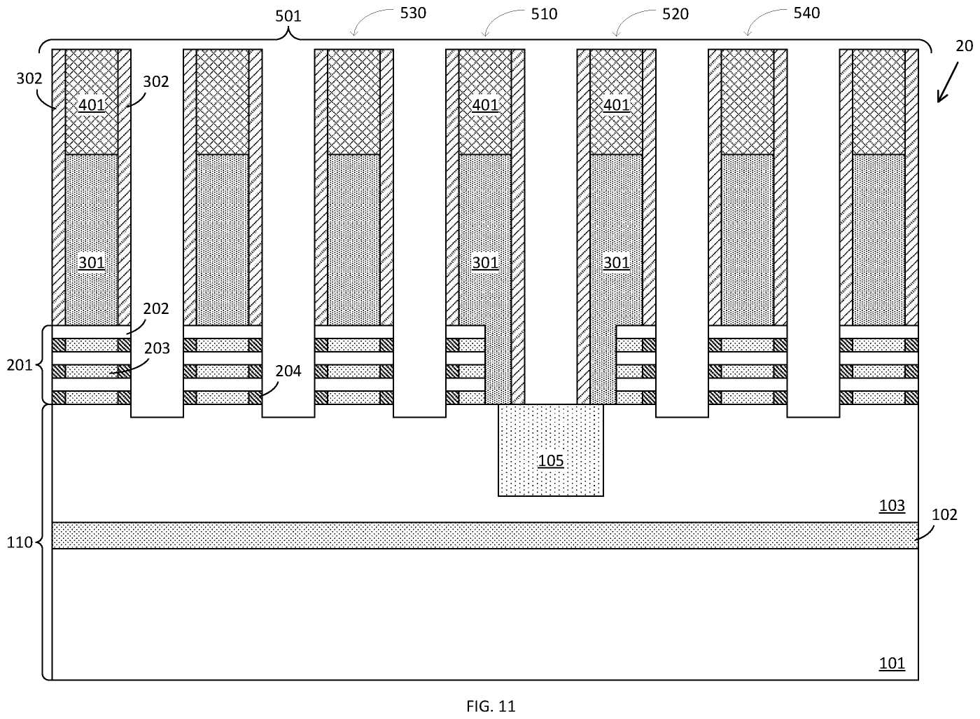

FIG. 11 is a demonstrative illustration of a cross-sectional view of a semiconductor structure in a step of manufacturing thereof according to one embodiment of present invention. More particularly, following the step illustrated in FIG. 10, embodiments of present invention provide forming sidewall spacers 302 at sidewalls of the set of sacrificial gates 301, and recessing or etching the raw stack of nanosheets 201 to create a plurality of stacks of nanosheets, which subsequently forms an array of transistors 501. For example, the array of transistors 501 may include a first set of transistors and a second set of transistors. As is described below in more details, the first set of transistors may include a first dummy transistor 510 and a second dummy transistor 520, and the second set of transistors may include a first active transistor 530 and a second active transistor 540. On the other hand, in forming the array of transistors 501, the plurality of stacks of nanosheets may each include a set of nanosheets 202 and a set of sacrificial sheets 203 vertically between the set of nanosheets 202. Moreover, the first dummy transistor 510 may include a first sacrificial gate 301 that covers an end of a first set of nanosheets 202, and the second dummy transistor 520 may include a second sacrificial gate 301 that covers an end of a second set of nanosheets 202. A plurality of inner spacers 204 may be formed at the ends of the set of sacrificial sheets 203.

In one embodiment, the sidewall spacers 302 and the inner spacers 204 may be nitride such as SiN; the set of nanosheets 202 may be Si or SiGe with a first Ge concentration level; and the set of sacrificial sheets 203 may be SiGe with a second Ge concentration level. The Ge concentration level of the set of nanosheets 202 may range, for example, from 25% to 35% and may be different from the Ge concentration level of the set of sacrificial sheets 203, which may range, for example, from 45% to 55% such that the set of sacrificial sheets 203 may be selectively etched away in the presence of set of nanosheets 202.

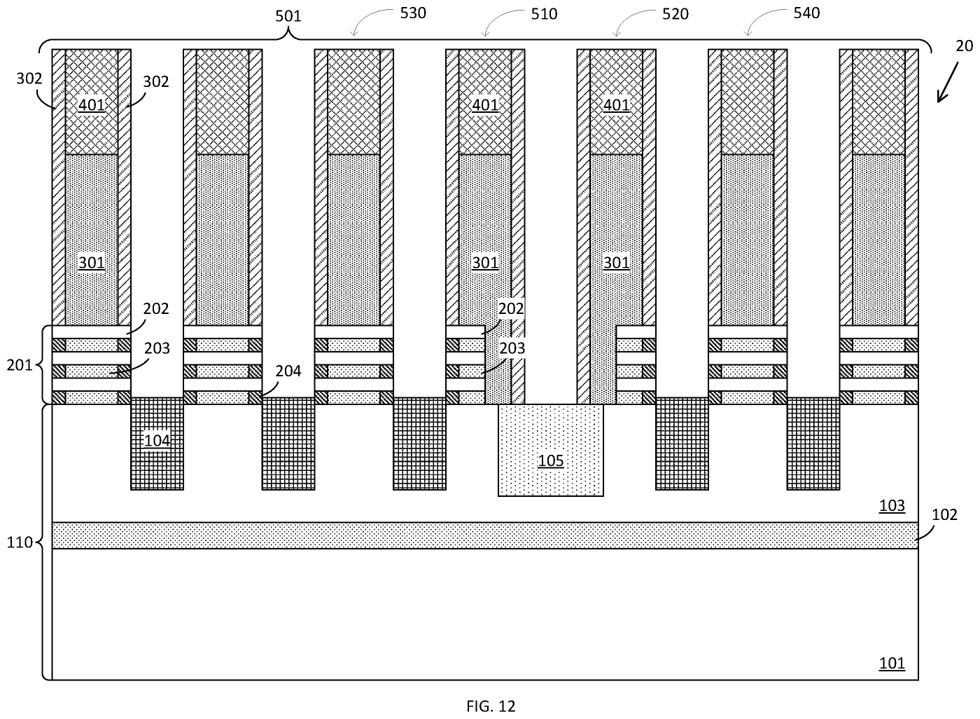

FIG. 12 is a demonstrative illustration of a cross-sectional view of a semiconductor structure in a step of manufacturing thereof according to one embodiment of present invention. More particularly, following the step illustrated in FIG. 11, embodiments of present invention provide forming a set of sacrificial placeholders 104 in the silicon layer 103 and in areas between the array of transistors 501 or more particularly between the set of sacrificial gates 301, except in the area where the dummy diffusion break 105 is formed between the first dummy transistor 510 and the second dummy transistor 520. The set of sacrificial placeholders 104 may be made or formed by first recessing, through a selective etching process, the silicon layer 103 to create recesses and subsequently depositing a material suitable for the sacrificial placeholders 104 such as, for example polysilicon, SiO₂, or SiN, in the recesses in the silicon layer 103.

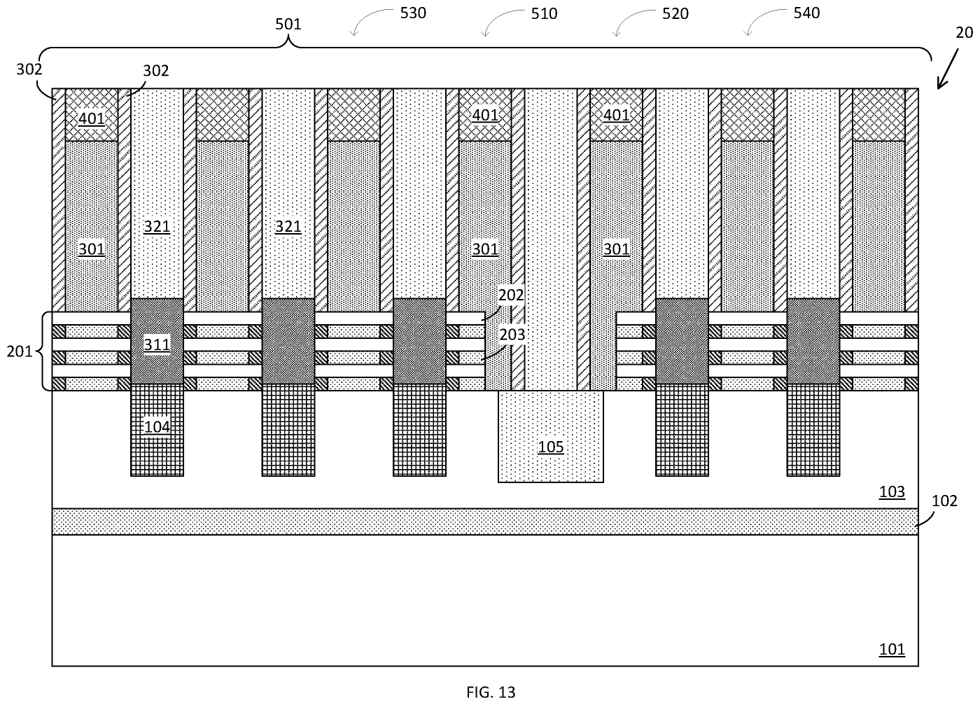

FIG. 13 is a demonstrative illustration of a cross-sectional view of a semiconductor structure in a step of manufacturing thereof according to one embodiment of present invention. More particularly, following the step illustrated in FIG. 12, embodiments of present invention provide forming source/drain regions 311 of the array of transistors 501 through an epitaxial growth process. The source/drain regions 311 may be formed between the ends of any two neighboring stacks of nanosheets, such as between the nanosheets 202 and between the inner spacers 204 and be formed directly above the sacrificial placeholders 104. The source/drain regions 311 may include Si or SiGe in material. However, since the dummy diffusion break 105 is of dielectric material such as, for example SiO₂, no epitaxial growth may be formed above the dummy diffusion break 105.

Following the formation of the source/drain regions 311, embodiments of present invention provide filling the space or opening above the source/drain regions 311 between the sacrificial gates 301 with a dielectric layer 321. In one embodiment, the dielectric layer 321 may be an interlevel dielectric layer made of a material, such as SiO₂, that provide etch selectivity with the sidewall spacers 302 and the underneath sacrificial placeholders 104. A chemical-mechanic-polishing (CMP) process may be applied to planarize a top surface of the semiconductor structure 20, resulting in at least some portion of the hard masks 401 and sidewall spacers 302 being removed.

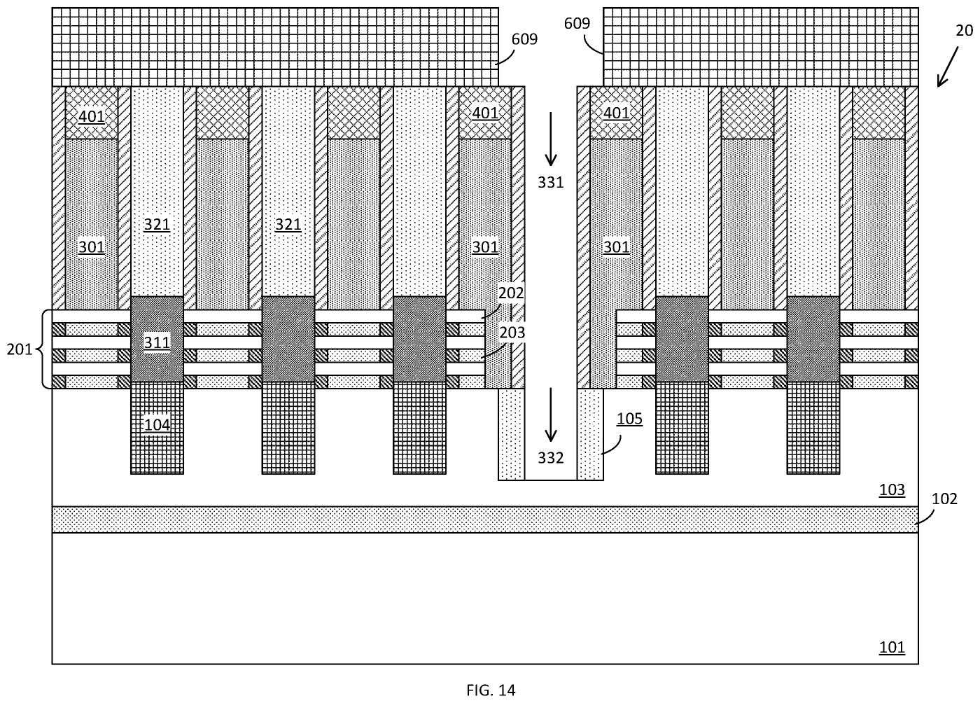

FIG. 14 is a demonstrative illustration of a cross-sectional view of a semiconductor structure in a step of manufacturing thereof according to one embodiment of present invention. More particularly, following the step illustrated in FIG. 13, embodiments of present invention provide forming an organic planarization layer (OPL) at the planarized top surface of the semiconductor structure 20 above the hard mask 401 and the dielectric layer 321, and patterning the OPL layer to form a hard mask 609. According to one embodiment, a hard mask used in patterning the dummy diffusion break 105 may be used or re-used here, therefore eliminating the need of creating a new hard mask thereby saving cost. The hard mask 609 exposes the dielectric layer 321 between the first dummy transistor 510 and the second dummy transistor 520, and the exposed dielectric layer 321 may be removed in a selective etching process to create an opening 331 between the sacrificial gates 301 of the first and the second dummy transistors 510 and 520.

Embodiments of present invention further provide etching the dummy diffusion break 105 underneath the dielectric layer 321 to create an opening 332 in the dummy diffusion break 105 that exposes the underneath silicon layer 103. The dummy diffusion break 105 and the sidewall spacers 302 may be of different materials such as, for example SiO₂ and SiN respectively, such that the exposed portion of dummy diffusion break 105 may be removed in a selective etching process, resulting in the opening 332 that is surrounded by the remaining portion of the dummy diffusion break 105.

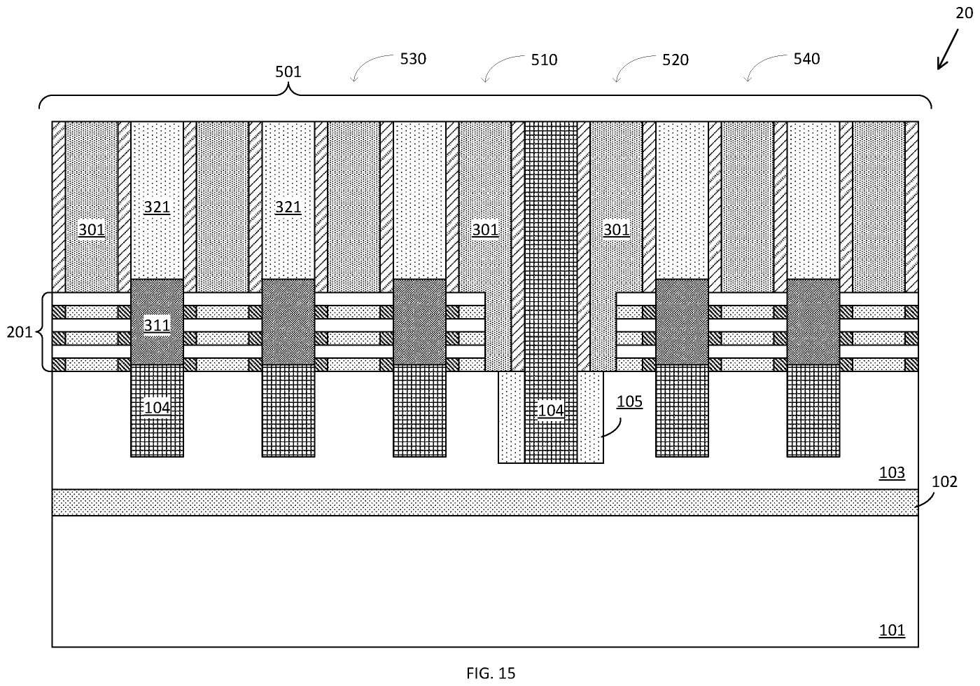

FIG. 15 is a demonstrative illustration of a cross-sectional view of a semiconductor structure in a step of manufacturing thereof according to one embodiment of present invention. More particularly, following the step illustrated in FIG. 14, embodiments of present invention provide filling the openings 331 and 332 with a dielectric material. In one embodiment, a same dielectric material as that used in forming the sacrificial placeholder 104 may be used in filling the openings 331 and 332. After filling the openings 331 and 332, a CMP process may be applied to polish and subsequently remove the hard masks 401 and create a planarized surface that exposes the sacrificial gates 301.

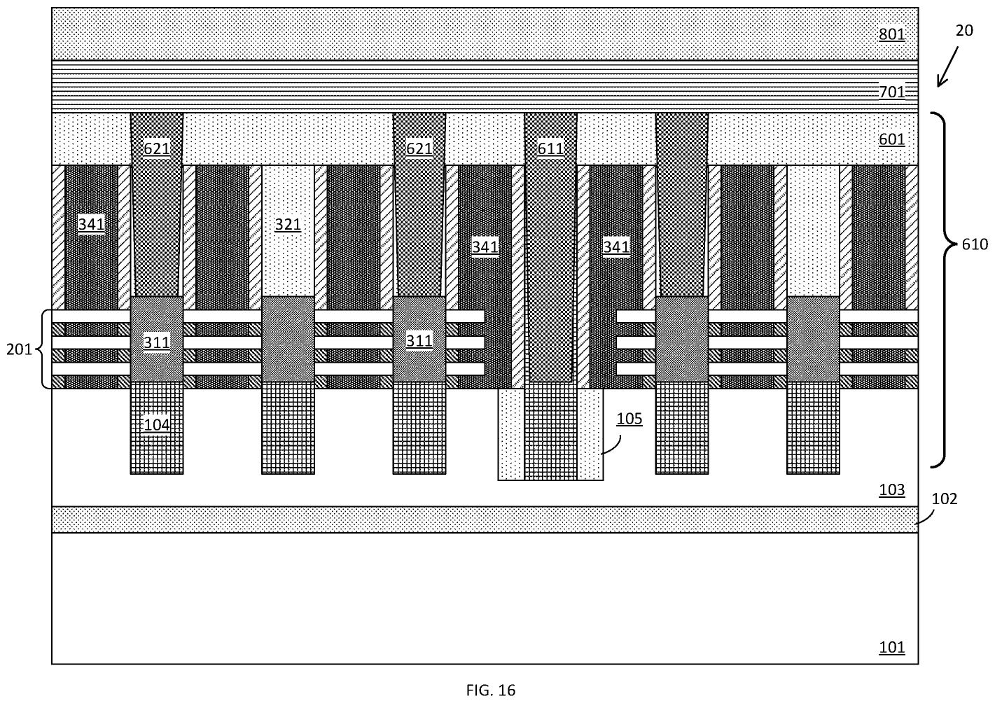

FIG. 16 is a demonstrative illustration of a cross-sectional view of a semiconductor structure in a step of manufacturing thereof according to one embodiment of present invention. More particularly, following the step illustrated in FIG. 15, embodiments of present invention provide selectively removing the sacrificial gates 301 and the set of sacrificial sheets 203 between the set of nanosheets 202, and forming replacement metal gates 341 that surround or wrap around the set of nanosheets 202 as well as above the set of nanosheets 202. In one embodiment, the replacement metal gates 341 of the first and the second dummy transistor 510 and 520 may be dummy gates and may be adjacent to the metal connection 610.

Next, embodiments of present invention provide forming, such as through deposition, a dielectric layer 601 above the semiconductor structure 20, covering the replacement metal gates 341, the dielectric layer 321, and the sacrificial placeholder 104 between the first and the second dummy transistor 510 and 520. Following the formation of the dielectric layer 601, one or more openings may be created, through a lithographic patterning and etching process, through the dielectric layer 601, through the dielectric layer 321 to expose one or more source/drain regions 311 of other active transistors, and partially into the sacrificial placeholder 104 between the first and the second dummy transistor 510 and 520. In one embodiment, the opening created in the sacrificial placeholder 104 between the first and the second dummy transistor 510 and 520 may have a depth substantially close to a top surface of the silicon layer 103. Next, a conductive material such as, for example, metal may be used to fill the opening or openings to form a first portion 611 of a metal connection 610 between the first and the second dummy transistor 510 and 520 and, for example, form a source/drain contact 621 above one of the source/drain regions 311 of an active transistor such as the first active transistor 530. The first portion 611 of the metal connection 610 may be between the first and the second dummy gate of the first and the second dummy transistor 510 and 520 and may be electrically isolated from the first and the second dummy gate. In other words, the end of the first and the second set of nanosheets 202 of the first and the second dummy transistor 510 and 520 may be separated and/or insulated from the metal connection 610, and in particular from the first portion 611 of the metal connection 610 by at least the sidewall spacers 302.

Embodiments of present invention further provide forming other middle-of-line (MOL) structures and a back-end-of-line (BEOL) 701 on top of the dielectric layer 601 in contact with one or more of the source/drain contacts 621 and in contact with the first portion 611 of the metal connection 610. For example, at least one metal contact in the BEOL 701, at the frontside of the semiconductor structure 20, is in contact with the metal connection 610 or more particularly with the first portion 611 of the metal connection 610. A carrier wafer 801 is then bonded onto the semiconductor structure 20 for further device processing from a backside of the semiconductor structure 20.

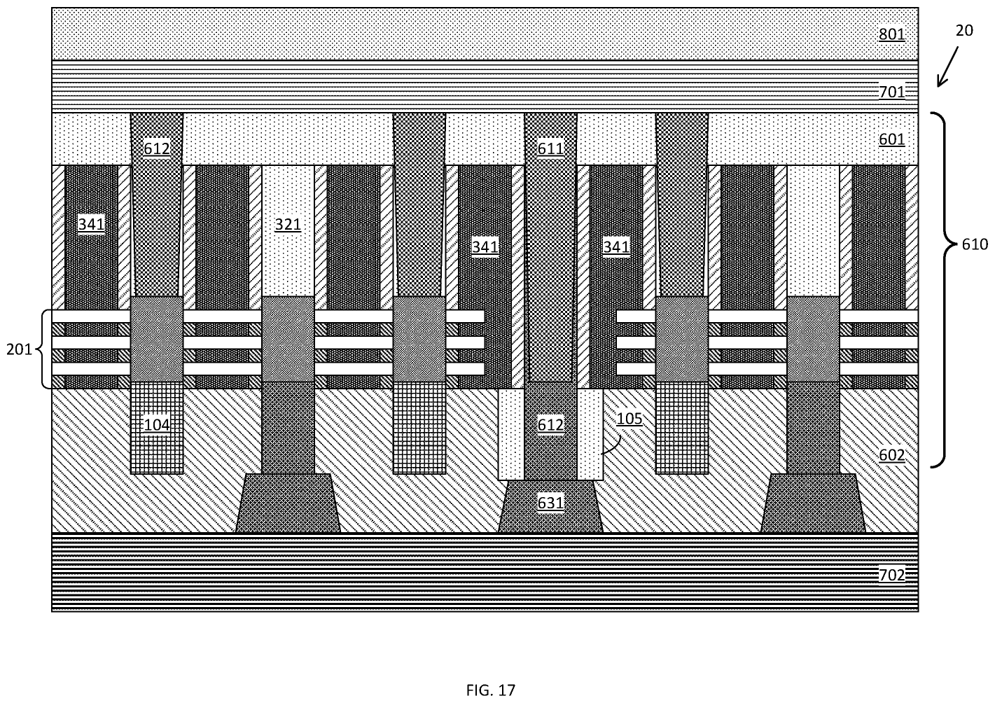

FIG. 17 is a demonstrative illustration of a cross-sectional view of a semiconductor structure in a step of manufacturing thereof according to one embodiment of present invention. More particularly, following the step illustrated in FIG. 16, embodiments of present invention provide removing the bulk silicon substrate 101 through a CMP process or a selective etching process to stop at the etch-stop layer 102, removing the etch-stop layer 102, and selectively removing the silicon layer 103 relative to the sacrificial placeholders 104 and the dummy diffusion break 105. A backside interlevel dielectric layer 602 may subsequently be formed to cover the backside of the plurality of stacks of nanosheets and the sacrificial placeholders 104. After forming the backside interlevel dielectric layer 602, one or more openings may be created in the backside interlevel dielectric layer 602. One or more of the sacrificial placeholders 104, including at least the sacrificial placeholder 104 that is surrounded by the dummy diffusion break 105, may be exposed. The exposed sacrificial placeholders 104 may be removed in selective etching process, relative to the dummy diffusion break 105. For example, a bottom surface of the first portion 611 of the metal connection may be exposed by the removal of the sacrificial placeholder 104. A conductive material such as metal, and in one embodiment the same metal as that used in forming the first portion 611 of the metal connection, may be used to form a second portion 612 of the metal connection 610. In other words, in one embodiment, the metal connection 610 may include the first portion 611 and the second portion 612 with the first portion 611 and the second portion 612 being made of a same metal material.

Embodiments of present invention may further provide forming one or more backside contacts in the backside interlevel dielectric layer 602 and at least one of the backside contacts, such as a backside contact 631, which may be a metal contact, is in contact with the second portion 612 of the metal connection 610. A backside interconnect structure 702 may subsequently be formed above the one or more backside contacts or metal contacts and above the backside interlevel dielectric layer 602.

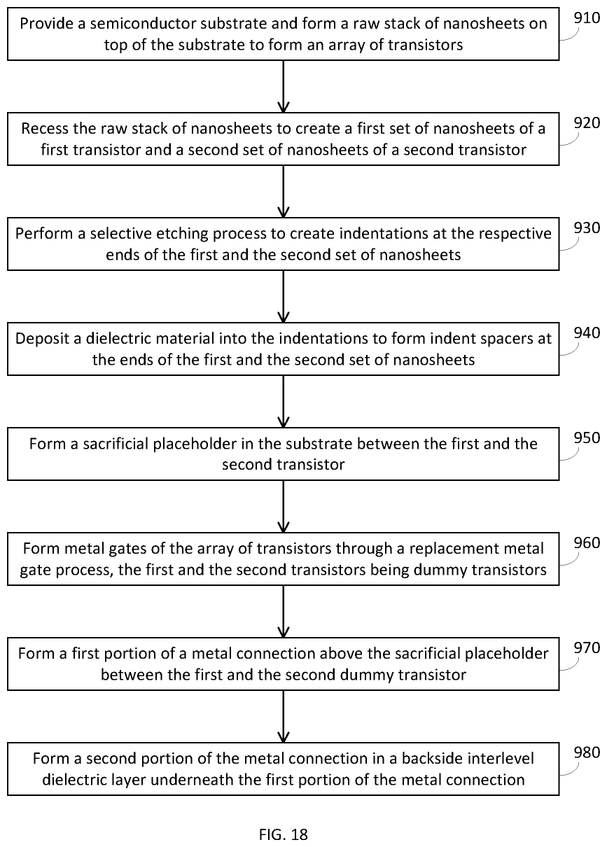

FIG. 18 is a demonstrative illustration of a flow-chart of a method of manufacturing a semiconductor structure according to embodiments of present invention. The method includes (910) forming providing a semiconductor substrate and form a raw stack of nanosheets on top of the substrate to form an array of transistors, wherein the semiconductor substrate may include an etch-stop layer for process purpose; (920) recessing or etching the raw stack of nanosheets to create a first set of nanosheets for a first transistor of the array of transistors; and a second set of nanosheets for a second transistor of the array of transistors; (930) performing a selective etching process to create indentations at the respective ends of the first and the second set of nanosheets; (940) depositing a dielectric material into the indentations to form indent spacers at the ends of the first and the second set of nanosheets; (950) form at least one sacrificial placeholder in the substrate in an area between the first and the second transistor; (960) form metal gates of the array of transistors through a replacement metal gate (RMG) process with the first and the second transistors being a first and a second dummy gate; (970) form a first portion of a metal connection above the sacrificial placeholder between the first and the second dummy transistor; and (980) form a second portion of the metal connection in a backside interlevel dielectric layer directly underneath the first portion of the metal connection to finish forming the metal connection.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions above have been presented for the purposes of illustration of various embodiments of present invention and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
an array of transistors on a semiconductor substrate, the array of transistors including a first transistor and a second transistor, the second transistor being next to the first transistor; and
a metal connection between the first transistor and the second transistor,
wherein the metal connection connects a first metal contact at a frontside of the array of transistors to a second metal contact at a backside of the array of transistors.

2. The semiconductor structure of claim 1, wherein a source/drain region of the first transistor and a source/drain region of the second transistor are filled with the metal connection, rendering the first transistor being a first dummy transistor and the second transistor being a second dummy transistor.

3. The semiconductor structure of claim 2, wherein the first dummy transistor includes a first dummy gate that surrounds a first set of nanosheets, the first set of nanosheets has a first section adjacent to the metal connection and a second section adjacent to a source/drain region of an active transistor, wherein the first section and the second section of the first set of nanosheets comprise different material.

4. The semiconductor structure of claim 3, wherein the first section of the first set of nanosheets comprises a dielectric material and the second section of the first set of nanosheets comprises a silicon material, and the first section of the first set of nanosheets electrically isolates the metal connection from the second section of the first set of nanosheets.

5. The semiconductor structure of claim 4, wherein the metal connection is further electrically isolated from the first dummy gate by a plurality of inner spacers between the first set of nanosheets and by a sidewall spacer above the first set of nanosheets.

6. The semiconductor structure of claim 5, wherein the metal connection includes a first portion between the first and the second dummy gate and between the first and the second set of nanosheets, and a second section that is surrounded by a backside interlevel dielectric layer underneath the first and the second dummy transistor.

7. The semiconductor structure of claim 2, wherein the first dummy transistor includes a first dummy gate that surrounds an end of a first set of nanosheets, and the metal connection is separated from the end of the first set of nanosheets at least by the first dummy gate.

8. The semiconductor structure of claim 7, wherein the metal connection includes a first portion between the first and the second dummy transistor, and a second portion that is surrounded by a dummy diffusion break, and the dummy diffusion break is further surrounded by a backside interlevel dielectric layer underneath the first and the second dummy transistor.

9. A method comprising:
forming an array of transistors on a substrate, the array of transistors including a first transistor and a second transistor, the second transistor being next to the first transistor;
forming a sacrificial placeholder in the substrate and between the first and the second transistor;
forming a first portion of a metal connection above the sacrificial placeholder between the first and the second transistor; and
forming a second portion of the metal connection in a backside interlevel dielectric layer directly underneath the first portion of the metal connection.

10. The method of claim 9, wherein forming the array of transistors comprises:
forming a raw stack of nanosheets on top of the substrate; and
recessing the raw stack of nanosheets to create a first set of nanosheets and a second set of nanosheets, wherein the first transistor includes the first set of nanosheets, and the second transistor includes the second set of nanosheets.

11. The method of claim 10, wherein forming the array of transistors further comprises performing a selective etching process of the first and the second set of nanosheets via an opening between the first and the second transistor to create a first set of indentations at the first set of nanosheets and a second set of indentations at the second set of nanosheets.

12. The method of claim 11, further comprises depositing a dielectric layer into the first and the second set of indentations at the first and the second set of nanosheets and on top of the sacrificial placeholder, wherein forming the first portion of the metal connection comprises forming the first portion of the metal connection in the dielectric layer.

13. The method of claim 9, wherein forming the second portion of the metal connection comprises replacing the sacrificial placeholder with the second portion of the metal connection through a deposition process from a backside of the array of transistors.

14. The method of claim 9, further comprising:
forming a dummy diffusion break in the substrate and between the first and the second transistor; and
forming the sacrificial placeholder in the dummy diffusion break to be surrounded by the dummy diffusion break.

15. The method of claim 14, wherein forming the second portion of the metal connection comprises selectively removing the sacrificial placeholder from the dummy diffusion break, and filling an opening created by the removal of the sacrificial placeholder with the second portion of the metal connection.

16. The method of claim 9, further comprising replacing a source/drain region of the first transistor by the metal connection to render the first transistor a first dummy transistor.

17. A semiconductor structure comprising:
an array of transistors on a semiconductor substrate, the array of transistors including a first dummy transistor; a second dummy transistor next to the first dummy transistor; a first active transistor next to the first dummy transistor opposite the second dummy transistor; and a second active transistor next to the second dummy transistor opposite the first dummy transistor;
a metal connection between the first dummy transistor and the second dummy transistor,
wherein the metal connection connects a first metal contact at a frontside of the array of transistors to a second metal contact at a backside of the array of transistors.

18. The semiconductor structure of claim 17, wherein the first dummy transistor includes a first dummy gate that surrounds a first set of nanosheets, the first set of nanosheets has a first section adjacent to the metal connection and a second section adjacent to a source/drain region of the first active transistor, wherein the first section of the first set of nanosheets comprises a dielectric material and the second section of the first set of nanosheets comprises a silicon material.

19. The semiconductor structure of claim 18, wherein the metal connection includes a first portion between the first and the second dummy transistor, and a second section that is surrounded by a backside interlevel dielectric layer underneath the first and the second dummy transistor.

20. The semiconductor structure of claim 17, wherein the metal connection includes a first portion between the first and the second dummy transistor and a second section that is surrounded by a dummy diffusion break, and the dummy diffusion break is further surrounded by a backside interlevel dielectric layer underneath the first and the second dummy transistor.
